(19) United States
(12) Patent Application Publication
(10) Pub. No.: US 2025/0283211 A1
(43) Pub. Date: Sep. 11, 2025

(54) GRADED INDEX INORGANIC ANTIREFLECTION COATINGS PRODUCED BY MAGNETRON SPUTTERING

(71) Applicant: The Penn State Research Foundation, University Park, PA (US)

(72) Inventors: Christian J. Ruud, University Park, PA (US); Noel C. Giebink, University Park, PA (US); Jon-Paul Maria, University Park, PA (US)

(21) Appl. No.: 18/861,717

(22) PCT Filed: May 12, 2023
(86) PCT No.: PCT/US2023/022052

§ 371 Date: Oct. 30, 2024

Related U.S. Application Data
(60) Provisional application No. 63/366,113, filed on Jun. 9, 2022.

(51) Int. Cl. C23C 14/58; C23C 14/10; C23C 14/35

(52) U.S. Cl. CPC C23C 14/5873; C23C 14/10; C23C 14/35; C23C 14/5806

(57) ABSTRACT

Embodiments relate to a method of forming a nanoporous thin film. The method can involve co-sputtering SiO₂ and a sacrificial porogen to form a sacrificial porogen: SiO₂ composite film onto a substrate. The method can involve annealing the sacrificial porogen: SiO₂ composite film to form an annealed sacrificial porogen: SiO₂ composite film. The method can involve dissolving at least a portion of the sacrificial porogen from the annealed sacrificial porogen: SiO₂ composite film.

### CROSS-REFERENCE TO RELATED APPLICATIONS

This patent application is related to and claims the benefit of priority to U.S. provisional patent application No. 63/366,113, filed on Jun. 9, 2022, the entire contents of which is incorporated herein by reference.

### STATEMENT REGARDING FEDERALLY SPONSORED RESEARCH OR DEVELOPMENT

This invention was made with government support under Grant No. DE-AR0000626 awarded by the Department of Energy/ARPA-E. The Government has certain rights in the invention.

### FIELD OF THE INVENTION

Embodiments relate to a method of forming a nanoporous thin film via co-sputtering SiO₂ and a sacrificial porogen to form a composite, annealing the composite, and dissolving at least a portion of the sacrificial porogen from the composite.

### BACKGROUND OF THE INVENTION

Graded-index multilayer antireflection (AR) coatings provide good AR performance for optical elements, windows, solar panels, etc., but the current techniques for fabricating these coatings are not economical and cannot be scaled to large area. Conventional methods use physical vapor deposition and sputtering to create multi-phase films from which one phase is removed, leaving behind a nanoporous structure. In addition, conventional methods produce an organic polymer (PTFE) nanoporous network instead of a hard silica nanoporous network.

Conventional coatings can be appreciated from U.S. Pat. Nos. 6,054,206, 9,732,427, 11,088,291, US 2014/0268348, and EP 2720986.

### BRIEF SUMMARY OF THE INVENTION

Embodiments disclosed herein provide a material composition and a process to enable fabrication of graded-index multilayer AR coatings via magnetron sputtering, which can be used to coat display glass, low-e glass, etc.

For example, an exemplary embodiment relates to methods of fabricating nanoporous multilayer silica thin films via magnetron sputtering. Silica and another material (e.g., ZnO) can be co-sputtered together to form a mixed film, annealed to induce phase segregation, and then the ZnO is dissolved away in a dilute acid solution to leave behind a nanoporous silica scaffold. One distinction of the inventive method is the use of a rapid thermal annealing step to achieve the needed phase segregation. For embodiments in which the substrate is SiO₂ and the other material is ZnO, there is a specific temperature range around 800° C. that enables the phase segregation to occur optimally; lower than 750° C. and higher than 850° C. does not work. The results is a thin film and a process providing the ability to control nanoporosity (and therefore the refractive index) with nanometer precision, which further enables fabrication of ultrahigh performance antireflection coatings.

An exemplary embodiment can relate to a method of forming a nanoporous thin film. The method can involve co-sputtering SiO₂ and a sacrificial porogen to form a sacrificial porogen: SiO₂ composite film onto a substrate. The method can involve annealing the sacrificial porogen: SiO₂ composite film to form an annealed sacrificial porogen: SiO₂ composite film. The method can involve dissolving at least a portion of the sacrificial porogen from the annealed sacrificial porogen: SiO₂ composite film.

In some embodiments, the substrate can include Si.

In some embodiments, the sacrificial porogen can be ZnO or B₂O₃.

In some embodiments, co-sputtering can involve magnetron sputtering.

In some embodiments, sputtering gas used in magnetron sputtering can include argon, xenon, oxygen, and/or nitrogen.

In some embodiments, annealing can induce phase segregation of the sacrificial porogen: SiO₂ composite film.

In some embodiments, phase segregation can yield nanoclusters of propogen embedded in a SiO₂ matrix.

In some embodiments, annealing can involve rapid thermal annealing.

In some embodiments, rapid thermal annealing can involve subjecting the sacrificial porogen: SiO₂ composite film to a temperature within a range from 750° C. and 850° C.

In some embodiments, annealing can involve rapid thermal annealing the sacrificial porogen: SiO₂ composite fil within a N₂ environment.

In some embodiments, dissolving can involve etching.

In some embodiments, etching can involve immersing the annealed sacrificial porogen: SiO₂ composite film in an acid.

In some embodiments, the acid can be HCl.

In some embodiments, the acid can be 0.1M of HCl.

In some embodiments, dissolving can be performed a room temperature.

In some embodiments, dissolving at least a portion of the sacrificial porogen from the annealed sacrificial porogen: SiO₂ composite film can involve removing sacrificial porogen so that the content of the sacrificial porogen within the nanoporous thin film is within a range from 0% to 1%.

In some embodiments, the method can involve tuning a refractive index of the nanoporous thin film by adjusting amount of sacrificial porogen used in the co-sputtering step.

In some embodiments, the method can involve treating the nanoporous thin film to make it hydrophobic.

In some embodiments, treating the nanoporous thin film to make it hydrophobic can involve fluorosilane treatment.

In some embodiments, the substrate can be glass used for a lens, low-e glass, a display, or a cover glass on a solar panel.

Further features, aspects, objects, advantages, and possible applications of the present invention will become apparent from a study of the exemplary embodiments and examples described below, in combination with the Figures, and the appended claims.

### BRIEF DESCRIPTION OF THE FIGURES

The above and other objects, aspects, features, advantages, and possible applications of the present invention will be more apparent from the following more particular description thereof, presented in conjunction with the following drawings. It should be understood that like reference numbers used in the drawings may identify like components.

FIG. 1 shows an exemplary fabrication process flow.

FIG. 2 shows refractive index dispersion of nanoporous films with different initial ZnO molar fractions.

FIG. 3 shows measured refractive index, inferred porosity, and retained thickness fraction of post-etch films with varying initial ZnO content.

FIG. 4 shows scanning electron micrographs and a cross-sectional view of a bilayer film.

FIG. 5 shows normal incidence transmission spectrum for a bare and double-side AR-coated fused silica wafer.

FIG. 6 shows measured and simulated net reflectivity (for both sides, averaged over the wavelength range shown in FIG. 5) for the same bare and double-side AR-coated fused silica wafer samples as a function of incidence angle.

FIG. 7 displays XPS depth profile of a bilayer coating on silicon before etching.

FIG. 8 displays XPS depth profile of a bilayer coating on silicon after etching.

FIG. 9 shows refractive index and retained thickness fraction of post-etch films after rapid thermal annealing for ten minutes at different temperatures.

FIG. 10 shows X-ray diffraction patterns of 51 mol % ZnO:SiO₂ films deposited on silicon and annealed at different temperatures.

FIG. 11 shows differential interference contrast images of a cross-hatched, 180° tape pull adhesion test performed on a n≈1.11 film for the film before the test (image a), the film after the test (image b) showing adhesive residue left behind by the tape, the appearance of the film after dissolving away the adhesive residue in solvent (image c), and scratches and removal of the film after rubbing with a cotton-tipped swab (image d).

FIG. 12 shows normal incidence specular transmittance of a double-side AR coated fused silica wafer before and after UV and humidity environmental testing.

FIG. 13 shows refractive index dispersion of nanoporous films before and after submerging the films in deionized water for 48 hrs.

FIG. 14 compares the water contact angle measured by with a calibrated goniometer (Rame-hart model 260) of bare fused silica to nanoporous films ranging from n=1.45 to n=1.12.

FIG. 15 shows solar spectrum-averaged (400-1100 nm) reflectivity as a function of incidence angle for bare glass (1), the single layer sol-gel nanoporous silica AR coating currently in use (2), and a trilayer coating following the results of this work (3).

FIG. 16 shows fractional increase in annual energy yield calculated for a PV panel with a trilayer AR coating on its cover glass compared to one with bare cover glass or the current single layer sol-gel AR coating.

### DETAILED DESCRIPTION OF THE INVENTION

The following description is of an embodiment presently contemplated for carrying out the present invention. This description is not to be taken in a limiting sense but is made merely for the purpose of describing the general principles and features of the present invention. The scope of the present invention should be determined with reference to the claims.

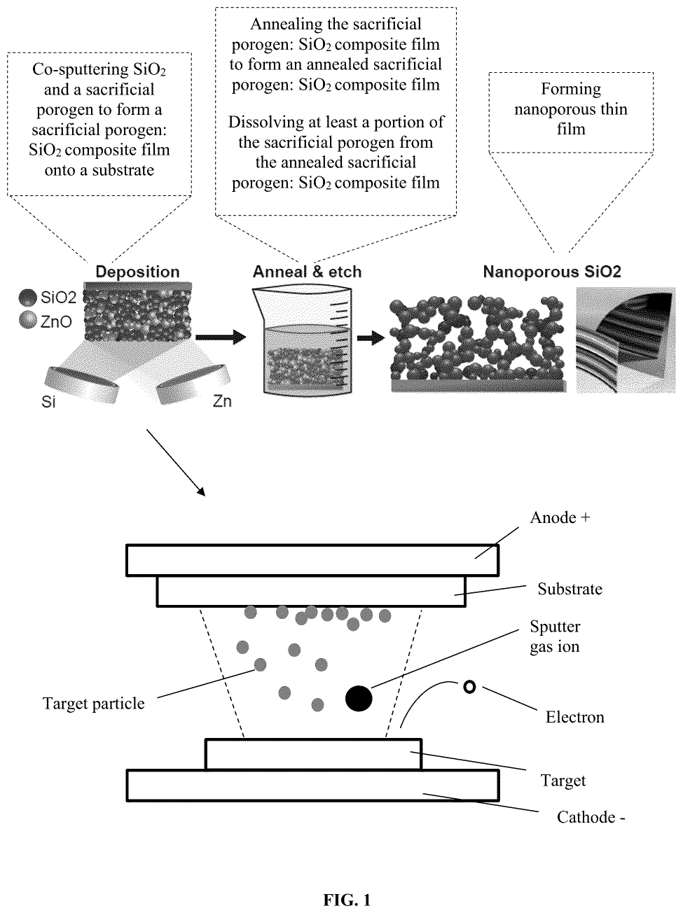

Referring to FIG. 1, embodiments relate to a method of forming a thin film. It is contemplated for the thin film to be a nanoporous thin film. The nanoporous thin film can be used as a coating. For example the thin film may be used as an antireflective (AR) coating. Some applications can include fabrication of a graded-index multilayer AR coating. As will be explained herein, the present disclosure provides material composition and processes to facilitate fabrication of an AR coating via magnetron sputtering. Magnetron sputtering is currently used to generate coatings on a large scale, and it is desirous to use magnetron sputtering to generate AR coatings that exhibit desired material properties.

The method can involve co-sputtering SiO₂ and a porogen to form a porogen: SiO₂ composite film onto a substrate. The SiO₂ and a porogen are co-sputtered together to form a mixed film, the mixed film being the porogen: SiO₂ composite film. A porogen is a particle of a specified shape and size that can be used to make pores in a structures. In this case, the porogen is used to make pores in the substrate. The substrate can be glass used for a lens, low-e glass, a display, a cover glass on a solar panel, etc. In this regard, it is contemplated for the substrate to be or include fused silica, float glass, optical glass, architectural glass, infrared optical materials such as ZnSe, ZnS or CaF₂, and semiconductors such as Si, Ge, or GaAs. While embodiments herein discuss SiO₂ as the matrix material, other matrix materials can be used (e.g., Al₂O₃, TiO₂, etc.). The selection of matrix material can be done to provide a desired refractive index. It is contemplated for the porogen to be sacrificial. For instance, it is contemplated for the porogen to be removed (as will be explained later) and discarded, the voids left due to the removal forming the porous structure within the substrate. The porogen can be ZnO, B₂O₃, Al₂O₃, MgO, TiO₂, Fe₂O₃, CuO, CaO, ZrO₂.

The co-sputtering can involve magnetron sputtering. Magnetron sputtering involves a technique that initiates plasma generation for the purposes of deposition. Generally, a magnetron system configuration includes a chamber with a cathode located adjacent a target (the target being the porogen in this case) at one side of the chamber and an anode located adjacent the substrate at another side of the chamber. The arrangement is such that the substrate and target subtend each other (i.e., the anode is behind the substrate and the cathode is behind the target). In an exemplary implementation, a first step is to initiate plasma generation. This can be achieved via application of high voltage between a cathode and an anode. Between the anode and cathode is a sputtering gas chamber which contains the sputtering gas. Applying the voltage causes electrons in the sputtering gas to be accelerated away from the cathode, which causes collisions with atoms of sputtering gas. This further causes an electrostatic repulsion to remove electrons from the sputtering gas atoms, thereby leading to ionization of the sputtering gas atoms. The positive sputter gas atoms are then accelerated towards the negatively charged cathode, which causes high energy collisions with the surface of the target. These collisions cause atoms at the surface of the target to be ejected into the vacuum environment of the chamber such that they reach the surface of the substrate and deposit thereon. The sputtering gas can be argon, xenon, etc., and in some cases can include other gases such as oxygen, nitrogen, etc. Magnets can be used to confine the electrons in the plasma at or near the surface of the target. Confining the electrons not only leads to a higher density plasma and increased deposition rates, but also prevents damage which would otherwise be caused by direct impact of electrons with the substrate or film being grown thereon.

Embodiments disclosed herein discuss use of reactive sputtering, wherein where pure Zn and Si are sputtered in an oxygen ambient to react to form ZnO and SiO2. However, it is understood that normal co-sputtering directly from ZnO and SiO2 targets, and perhaps even from a single ZnO—SiO₂ composite target could also be done. The selection of sputtering technique can provide technical advantages for certain types of manufacturing.

After film growth, the method can involve annealing the sacrificial porogen: SiO₂ composite film to form an annealed sacrificial porogen: SiO₂ composite film. It is contemplated for the annealing to induce phase segregation of the sacrificial porogen: SiO₂ composite film. The phase segregation can yield nanoclusters of propogen embedded in a SiO₂ matrix. The annealing can involve rapid thermal annealing. This can involve subjecting the sacrificial porogen: SiO₂ composite film to a predetermined temperature for a predetermine period of time—a temperature and time that will induce phase segregation. With the porogen being ZnO, this can involve subjecting the sacrificial porogen: SiO₂ composite film to a temperature within a range from 750° C. and 850° C., and preferably 800° C., and a time of 1 to 10 minutes under rapid thermal annealing, or 1-10 hours under conventional furnace annealing. It is contemplated that for B₂O₃, the anneal temperatures needed will be lower and the anneal time will be the same. The method can involve rapid thermal annealing the sacrificial porogen: SiO₂ composite within a N₂ environment or an Ar environment. Experimentation has shown that annealing below 750° C. does not achieve sufficient phase segregation (the porous film falls apart) and annealing above 850° C. leads to a new Zn silicate phase formation that does not dissolve away. Experimentation has also shown that there is no benefit to annealing for more than 10 minutes, but is also no problem associated with annealing for longer than 10 minutes.

After annealing, the method can involve dissolving at least a portion of the sacrificial porogen from the annealed sacrificial porogen: SiO₂ composite film. Dissolving the porogen is what forms the porous network within the film. With the film being SiO₂, the porous network forms a nanoporous silica scaffold. The porogen can be dissolved so that the content of the residual porogen within the nanoporous thin film is within a range from 0% to 10%. Dissolving can involve etching, which can include immersing the annealed sacrificial porogen: SiO₂ composite film in an acid from 30 to 60 seconds at room temperature (approximately 20° C.). If a warm acid bath is used, it is contemplated that the temperature can be between 20° C. and 80° C. The acid can be any acid that dissolves the porogen. This can be HCl, citric acid, etc. for ZnO, for example. In an exemplary embodiment, 0.1M-0.5M of HCl can be used.

The result is a nanoporous thin film that can be used as a coating (e.g., an AR coating) for the substrate. The substrate can be glass used for a lens, low-e glass, a display, a cover glass on a solar panel, etc. The nanoporous thin film can be formed on any portion or surface of the glass. The nanoporous thin film can be formed on multiple portions or multiple surfaces of the glass. The nanoporous thin film can be formed as a single layer or as multiple layers.

The refractive index of the nanoporous thin film can be tuned by adjusting amount of sacrificial porogen used in the co-sputtering step. For instance, with a SiO2 substrate and a ZnO porogen, use of a low molar fraction (e.g., 16 mol % of ZnO) yields an effective ref index (neff) of 1.35, whereas use of a high molar fraction (e.g., 39 mol % of ZnO) yields neff of 1.11.

The method can involve treating the nanoporous thin film to make it hydrophobic or more hydrophobic. For instance, the nanoporous thin film can be subjected to a fluorosilane treatment. This can be done to mitigate or prevent effects of water uptake in the porous structure changing the refractive index of the nanoporous thin film.

Antireflection (AR) coatings with graded refractive index profiles approaching air offer unparalleled AR performance, but conventional methods of fabricating the same lack a scalable fabrication process that allow them to be used more widely in applications such as architecture and solar energy conversion. Embodiments of the inventive method provide a sputtering-based sacrificial porogen process to fabricate multilayer nanoporous SiO₂ coatings with tunable refractive index down to neff=1.11. Using this approach, a step-graded bilayer AR coating with outstanding wide-angle AR performance (single side average reflectivity in the visible spectrum ranges from 0.2% at normal incidence to 0.7% at 40°), good adhesion, and promising environmental durability can be achieved. Results discussed herein demonstrate the ability to produce ultrahigh performance AR coatings over large area using industrial-scale magnetron sputtering systems.

Eliminating reflection from the air-glass interface is an age-old challenge that is important in applications ranging from photography to solar energy conversion. Simple solutions such as a quarter wave film of MgF₂ work well for narrowband light over a limited range of incidence angles; however, truly broadband, omnidirectional antireflection (AR) coatings are more difficult to achieve because they typically rely on grading the refractive index down close to that of air, either with motheye nanostructures or by carefully controlling nanoporosity throughout the coating. Glancing angle deposition is a well-known path to produce the latter, enabling step-graded nanoporous SiO₂ coatings that achieve outstanding AR performance, but unfortunately the process is not scalable. Conversely, sol-gel approaches currently used on photovoltaic cover glass are scalable, but limited to a single layer, which compromises their bandwidth and angular tolerance. Thus, it remains a challenge to achieve step-graded AR coatings that are both multilayer and scalable.

Embodiments of the method disclosed herein, demonstrate that magnetron sputtering—a deposition technique that is widely used in the production of low-e glass and large area displays—can be exploited to produce high performance step-graded AR coatings made from SiO₂. Using a sacrificial porogen approach based on co-sputtering of SiO₂ and ZnO followed by rapid thermal annealing and a dilute acid etch, nanoporous SiO₂ films with a range of refractive indices down to neff=1.11±0.01 can be achieved by varying the initial ZnO fraction. Using this technique to double-side coat a fused silica window, the average visible spectrum (380 nm<λ<750 nm) transmission can be improved from 93.2±0.1% to 99.5±0.1%, and the average reflection can be suppressed to <1% per side at incidence angles up to 40°. These demonstrate that ultrahigh performance step-graded AR coatings can be manufactured over large area on an industrial scale.

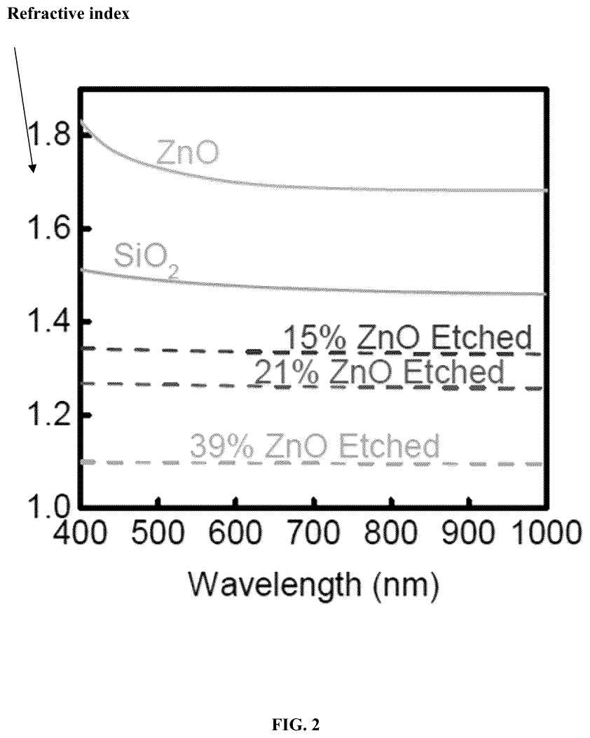

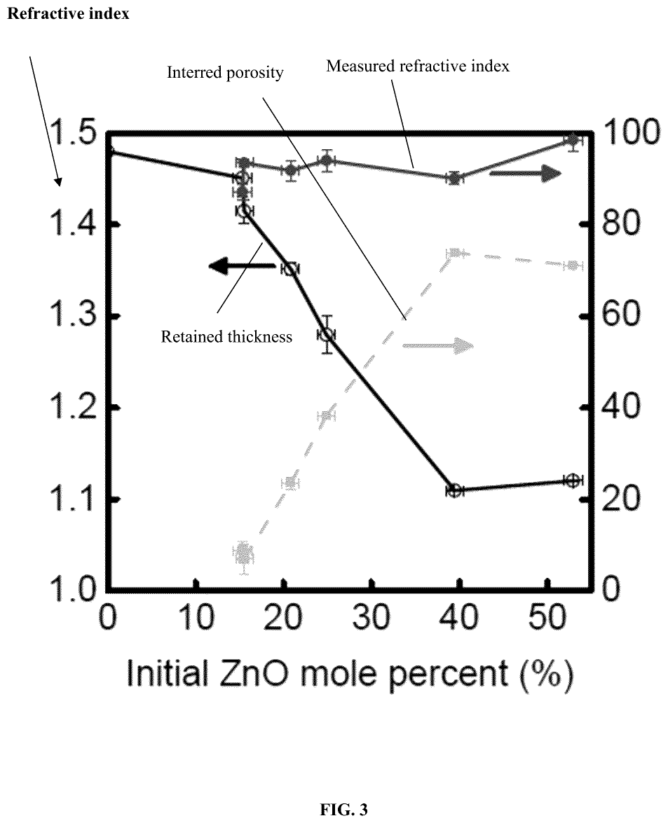

FIG. 1 illustrates an overview of an exemplary fabrication approach, which begins with reactive radio frequency co-sputtering of a ZnO:SiO₂ composite film onto a Si or fused silica substrate at ambient temperature. Previous work has shown that such ZnO:SiO2 composites phase segregate, yielding nanoclusters of ZnO embedded in a SiO₂ matrix. To ensure maximal phase segregation, the composite films are subsequently annealed in a nitrogen environment at 800° C. for 10 minutes using a rapid thermal annealing system. The annealed films are then immersed (e.g., rinsed) in dilute (0.1M) hydrochloric acid for approximately 30 seconds to selectively dissolve the ZnO, leaving behind a nanoporous SiO2 network that is specular by eye. The photograph with the ribbon cable on the right-hand side highlights the specular nature of a typical nanoporous film deposited on a Si wafer. FIG. 2 shows refractive index dispersion of nanoporous films with different initial ZnO molar fractions; the index of as-deposited neat SiO₂ and ZnO films are shown for reference. FIG. 2 shows that the refractive index of the etched films is nearly dispersionless and decreases with increasing initial ZnO content (as determined from X-ray photoelectron spectroscopy), reaching neff=1.1 at 39 mol % ZnO. FIG. 3 shows measured refractive index, inferred porosity, and retained thickness fraction of post-etch films with varying initial ZnO content. FIG. 3 compares the decrease in refractive index to the void fraction determined from a Bruggeman effective medium model. Beyond ˜20 mol % ZnO, the void fraction is higher than the initial ZnO content. Since the molar volume of ZnO is less than SiO₂, this trend suggests that some SiO₂ is also removed during the HCl etch. This is consistent with the observation that, at high ZnO concentration(>53 mol %), the retained film thickness begins to decrease, presumably also due to removal of SiO₂ as the nanoscale network becomes ever more tenuous.

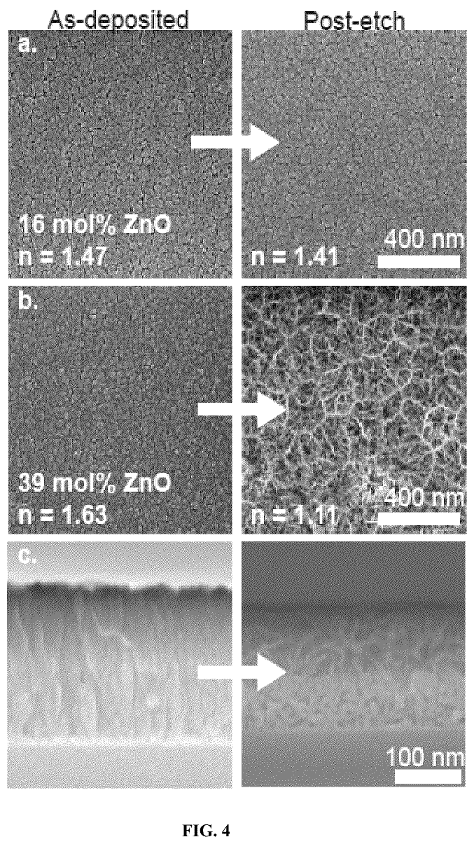

FIG. 4 shows scanning electron micrographs (image a) of a 16% ZnO:SiO2 composite film before and after etching, analogous micrographs (image b) for a 39% film, and cross-sectional view of a pre-and post-etch bilayer (image c) with the same initial ZnO fractions on a Si substrate. The scanning electron micrographs in FIG. 4 (images a and b) show how the film microstructure evolves upon going from low (16 mol %) to high (39 mol %) ZnO fraction before and after the etching step. Prior to etching, both films exhibit a granular microstructure with similar sub-50 nm feature sizes. The appearance of the low concentration film is largely preserved after etching (image a, neff≈1.35); however, it changes dramatically in the high concentration case, where the microstructure resembles a fibrous network with high void fraction (image b, neff=1.11). Image c of FIG. 4 shows a cross-sectional view of a bilayer film produced by depositing the same composite layers in sequence and then subjecting the sample to a single anneal and etching step. The different void fractions of the top and bottom layer are clearly evident and appear to be uniform throughout each layer, indicating that the etch step removes ZnO throughout the entire depth of the film. Depth-profiling X-ray photoelectron spectroscopy measurements confirm the discrete nature of the bilayer and that ZnO is fully removed after etching. Analysis of the etched film via ellipsometry yields layer thicknesses (d1=95±1 and d2=94±2 nm for the neff,1=1.31±0.01 and neff,2=1.11±0.01 bottom and top layers, respectively) that agree well with those obtained from the cross-sectional image c of FIG. 4.

To demonstrate the AR potential of these nanoporous films, a step-graded bilayer coating is designed to maximize transmission across the visible spectral range and applied to both sides of a fused silica wafer. The refractive index and layer thickness targets for the coating are summarized in Table 1, together with the experimental values (for both the front and back surfaces of the wafer) determined from ellipsometry. All but one of the coating parameters deviate from their design specification by <5%, highlighting the fidelity of this fabrication approach.

TABLE 1
AR Coating Parameters

| | Experiment | | Design | |
|---|---|---|---|---|
| | | Thickness | | Thickness |
| Layer | n_{eff} | (nm) | n_{eff} | (nm) |
| 1 (Top) | Front: 1.11 ± 0.01 | 120 ± 1 | 1.11 | 114 |
| | Back: 1.11 ± 0.01 | 96 ± 1 | | |
| 2 (Bottom) | Front: 1.37 ± 0.01 | 94 ± 1 | 1.32 | 96 |
| | Back: 1.41 ± 0.01 | 96 ± 1 | | |

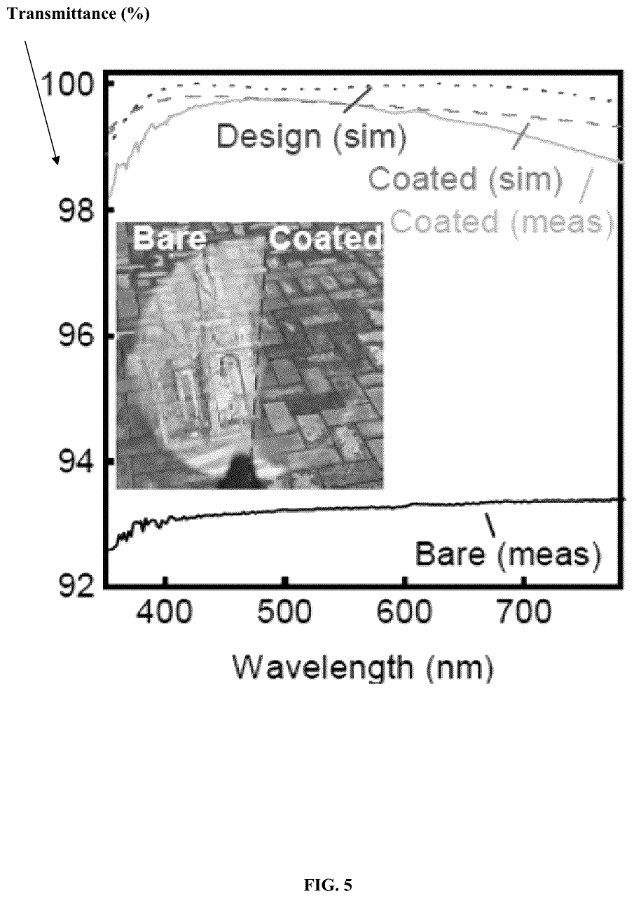

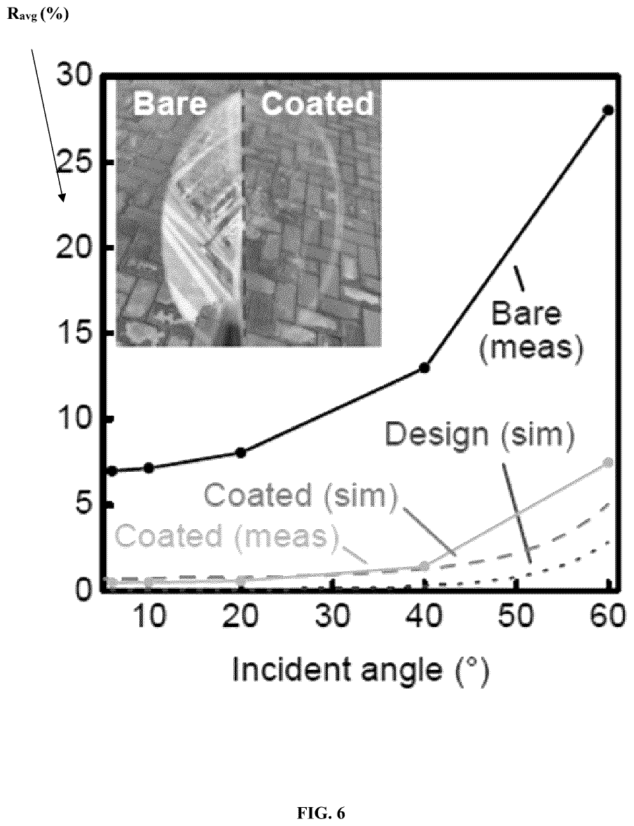

FIG. 5 shows normal incidence transmission spectrum for a bare and double-side AR-coated fused silica wafer. The dashed lines show the modeled transmission based on measured and designed parameters in Table 1. FIG. 6 shows measured and simulated net reflectivity (for both sides, averaged over the wavelength range shown in FIG. 5) for the same samples as a function of incidence angle. The inset photographs show the appearance of a typical sample outdoors; the left-hand side is uncoated for reference. FIG. 5 presents the normal incidence transmission spectrum measured for the double sidecoated wafer, which attains an average (over the wavelength range 380<λ<750 nm) transmittance of Tavg=99.5±0.1% compared with Tavg=93.2±0.1% for an uncoated wafer. FIG. 6 shows the corresponding average reflectance of the coated wafer (i.e. the net from both surfaces), which increases from Ravg=0.5±0.2% at 6° to just Ravg=1.4±0.2% at an angle of 40°. This difference is immediately apparent by eye, as shown in the inset photographs of a partially coated sample viewed at normal and oblique incidence on a sunny day. Transmission and reflection simulations are also included in FIGS. 5 and 6.

Most of the deviation between the design and measured data in FIGS. 5 and 6 can be explained by re-simulating with the experimental coating parameters from Table 1. The remaining deviation from experiment is at such a low level that it probably challenges some of the assumptions of the transfer matrix model (e.g. perfectly discrete interfaces and zero scattering). In this context, it is worth noting that relative deviations from the target reflectance (i.e. |Rmeas−Rtarget|/Rtarget) inherently become more sensitive to fabrication imperfections as Rtarget→0, even though the absolute deviations may be very small. Hence, although a multilayer coating with more index steps could further improve upon the wide angle(>40°) performance achieved in FIG. 6, there is little motivation to go beyond the current bilayer if low angle(<40°) antireflection is the primary goal.

To assess moisture uptake by these nanoporous coatings and its impact on their AR performance, the transmittance of a double side-coated wafer is measured before and immediately after 48 h in an 85° C. environmental chamber with 85% relative humidity. The humid environment slightly decreases the average transmittance from 99.3±0.1% to 98.7±0.1%, suggesting that water adsorption/infiltration in the nanoporous network is limited; fully filling the void space with water would have reduced the average transmittance to ˜96.5% according the effective medium model used.

This is consistent with ellipsometry measurements on single layer films, which show that immersing them in water for 48 hrs leads to slight increases in refractive index due to water uptake in the pore network. Rinsing the films in isopropyl alcohol (IPA) restores their refractive index (and AR coating transmittance) to its pristine value. Water uptake can be avoided entirely by treating the films with a fluorosilane to make them hydrophobic, as is commonly done for nanoporous sol-gel AR coatings.

In addition to damp heat testing, experiments were conducted to assess the mechanical durability, adhesion strength, and stability of the bilayer AR coating under accelerated ultraviolet (UV) light exposure. Cross-hatch tape pull tests indicate that the coating adheres strongly to the substrate; however, it has limited abrasion resistance and is easily removed by rubbing with a cotton swab. By contrast, the coating appears robust to UV light, with no change in transmittance observed following exposure to a dose of UV equivalent to one month of direct sunlight. These results therefore suggest that the coating could be durable enough for outdoor applications if the abrasion resistance can be improved.

The primary advantage of this new path to nanoporous SiO₂ AR coatings compared to existing sol-gel, glancing angle, or atomic layer deposition approaches, is that it combines the multi-layer graded index capability needed for wide angle, broadband operation, with the scalability of magnetron sputtering, which is used to coat millions of square meters of display and low-e glass every year. One application where ultrahigh performance AR coatings could deliver value is on the cover glass of solar panels, where the use of a step-graded trilayer coating would deliver a ˜4% boost in annual energy yield relative to the single layer sol-gel AR coating that is currently used.

A drawback of the current process, however, can be the high temperature of its annealing step (˜800° C.), which exceeds the softening point of most optical glasses. There is a relatively narrow temperature range between 750° C. and 850° C. that leads to optimal nanoporous film formation. Lower temperatures do not fully develop the SiO₂ network needed to prevent film collapse, whereas higher temperatures produce an insoluble zinc silicate phase. An alternative path to circumvent these challenges is to implement a B₂O₃—SiO₂ chemistry, which phase segregates at lower temperature than ZnO—SiO₂. Moreover, B₂O₃ is soluble in water (thereby avoiding the need for acid in the etching step) and is already widely used in industry as one of the basic ingredients in Pyrex glass.

In summary, embodiments involve use of a magnetron sputtering-based technique to fabricate multilayer nanoporous SiO₂ coatings with tunable refractive index down to neff=1.11. Using this approach, a step-graded bilayer coating with outstanding wide-angle AR performance, good adhesion, and promising environmental durability is demonstrated. It is contemplated that if the required annealing temperature is reduced to ˜620° C., it may be possible for the anneal to piggyback on the tempering process that most architectural and photovoltaic cover glass already goes through, thereby opening the door to industrial scale manufacturing of ultrahigh performance AR glass.

### Experimental Details

The following describes exemplary set-ups and techniques used for experimentation.

### Fabrication:

Reactive radio frequency magnetron co-sputtering is carried out in a Lesker CMS-18 sputter tool with three-inch diameter Si (99.999%) and Zn (99.99%) targets. All depositions are carried out at ambient temperature with a chamber pressure of 10 mT established using a 10:1 Ar:O₂ gas flow ratio.

Power on the Si target is held constant at 300 W while power on the Zn target is varied from 37 to 75 W, with corresponding net deposition rates varying between 0.3 to 1.8As−1. Samples are subsequently annealed at 800° C. in a N₂ environment for 10 minutes using an AccuThermo AW610 rapid thermal annealing system. They are then etched in 0.01M HCl at room temperature for at least 1 minute, rinsed with water and isopropanol, and blown dry with nitrogen.

### Morphological and Chemical Composition:

Film morphology is characterized by scanning electron microscopy and the chemical composition is ascertained by X-ray photoelectron spectroscopy using an Al K X-ray source (1.49 keV). Samples are charge-neutralized with low energy(<5 eV) electrons and Ar+ ions, and the binding energy is calibrated via the C 1 s 248.8 eV peak. Formation of crystalline phases with varied annealing temperatures is measured by XRD. Grazing incidence x-ray diffraction is measured at an incidence angle of 0.5° using a PANalytical Empyrean XRD in a parallel beam geometry with a double-bounce hybrid monochromator and a parallel-plate collimator.

### Optical Characterization:

Film thicknesses and refractive indices are determined via variable-angle spectroscopic ellipsometry (J. A. Woollam) using an isotropic Cauchy model. Nanoporous films are described in terms of their SiO₂ and air volume fractions using the Bruggeman effective medium approximation. All refractive index values specified in the text correspond to a wavelength of 633 nm. The transmittance and reflectance of multilayer stacks are modeled using the transfer matrix method and optimized for AR performance using a basin-hopping algorithm. The specular reflectance and transmittance of AR-coated samples is measured using unpolarized light in a Cary 7000 Universal Measurement Spectrophotometer.

### Environmental Characterization:

Damp heat testing is carried out in an environmental chamber (ESPEC SH-241) set to 85° C. and 85% relative humidity. Accelerated UV stability measurements are performed by exposing samples to the output of a laser-driven Xe arc lamp (LDLS EQ-99X) that produces an irradiance of ˜20 mWcm−2 in the 200 to 400 nm wavelength range.

As can be appreciated from the disclosure herein, a magnetron sputtering process is developed to produce nanoporous SiO₂ films with tunable porosity and refractive index as low as n=1.1. Graded index coatings fabricated with this technique yield outstanding antireflection performance, good adhesion, and promising environmental durability. These results offer a path to produce ultrahigh performance antireflection coatings on an industrial scale.

### Chemical Composition Profile of Bilayer Films

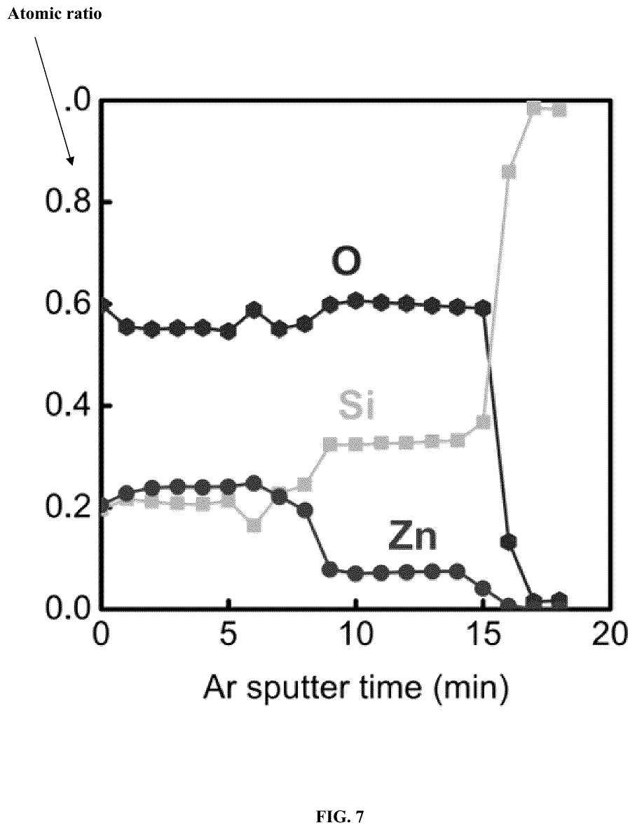

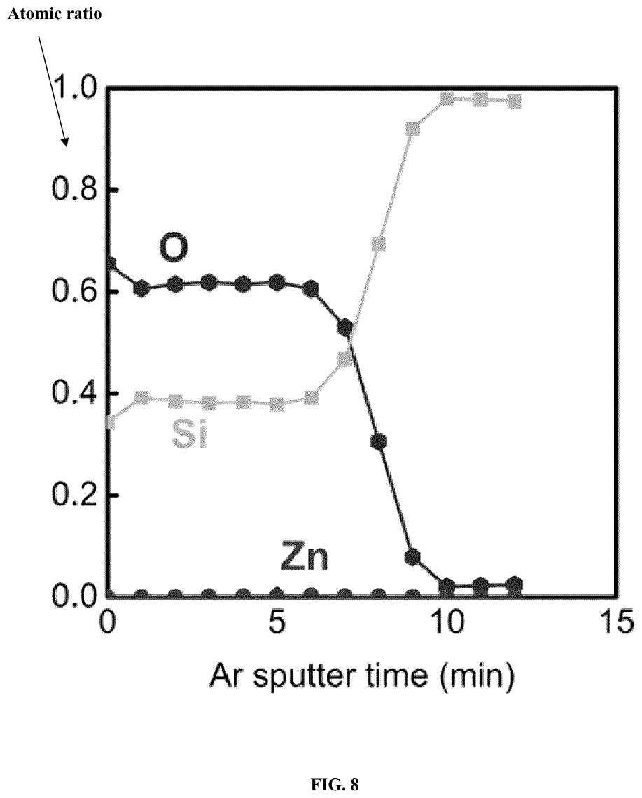

FIGS. 7 and 8 show XPS chemical composition depth profile of the composite bilayer and etched bilayer, respectively, obtained using Ar⁺ ion sputtering. FIG. 7 displays XPS depth profile of a bilayer coating on silicon before etching. FIG. 8 displays XPS depth profile of a bilayer coating on silicon after etching. The thickness and post-etch refractive index of the layers is d₂=95±1 nm and d₂=94±2 nm for the n_{eff,1}=1.31±0.01 and n_{eff,2}=1.11±0.01 bottom and top layers, respectively. A discrete step in the Zn concentration marks the internal interface in the as-deposited film. Layers of the graded-index coating are observed before etching with higher zinc loading in the top layer. Following the etch, Zn is completely removed, with less than 1% Zn measured at the surface and throughout the bulk of the sample.

### Impact of Annealing Temperature

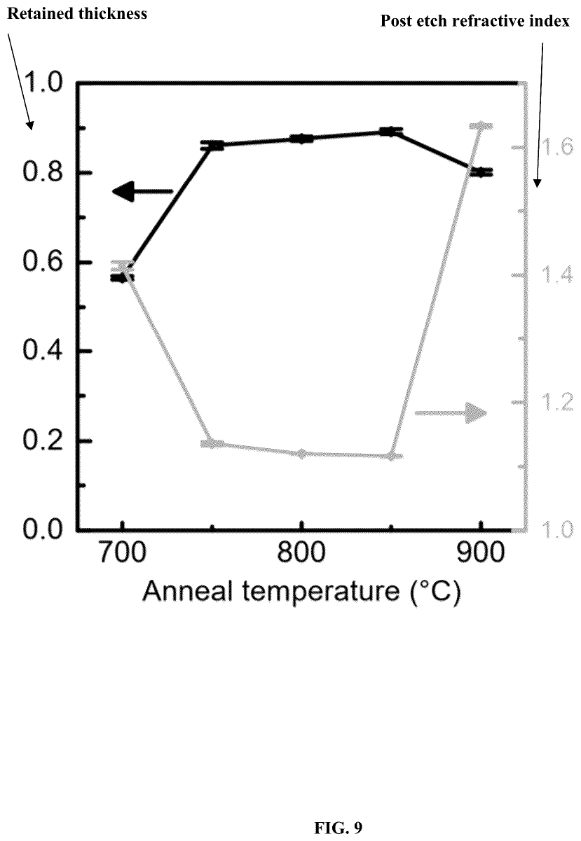

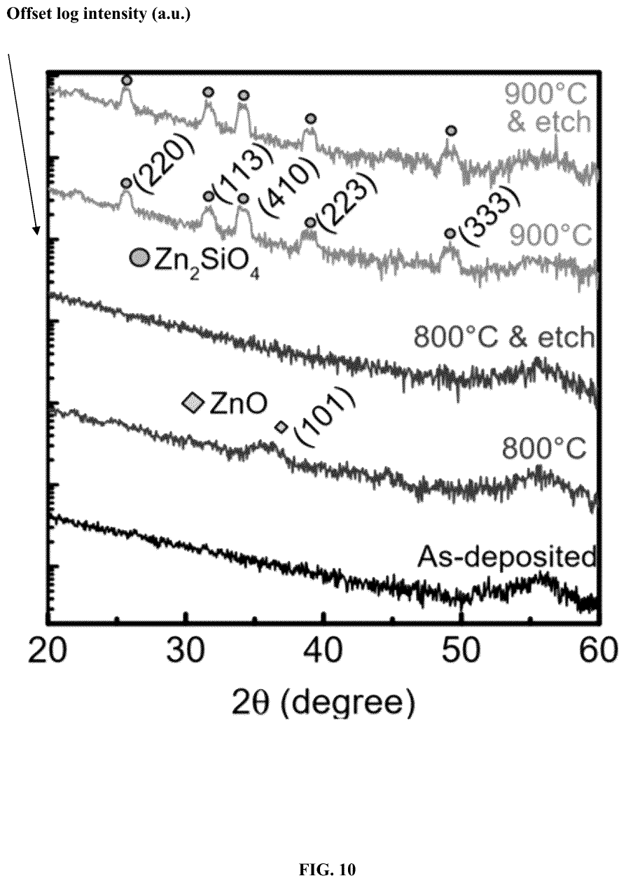

FIG. 9 shows refractive index and retained thickness fraction of post-etch films after rapid thermal annealing for ten minutes at different temperatures. FIG. 10 shows X-ray diffraction patterns of 51 mol % ZnO:SiO₂ films deposited on silicon and annealed at different temperatures. Weak diffraction from ZnO nanocrystals at 800° C. and 850° C. gives way to new peaks associated with the formation of an insoluble zinc silicate phase at 900° C. FIG. 9 tracks the effect of varying the anneal temperature on post-etch refractive index and retained film thickness for a 51 mol % ZnO:SiO₂ starting film. Below 750° C., the retained thickness decreases and the refractive index increases, indicating collapse of the nanoporous structure, presumably due to incomplete formation of a continuous SiO₂ network. Above 850° C., X-ray diffraction patterns shown in FIG. 10 indicate the formation of an insoluble willemite (Zn₂2SiO₄) phase, which causes the sharp increase in post-etch refractive index observed in FIG. 9. Thus, there is a relatively narrow temperature range between 750° C. and 850° C. that yields optimal phase segregation and ZnO nanocrystal formation needed for robust low index films.

### Adhesion and Environmental Durability Testing

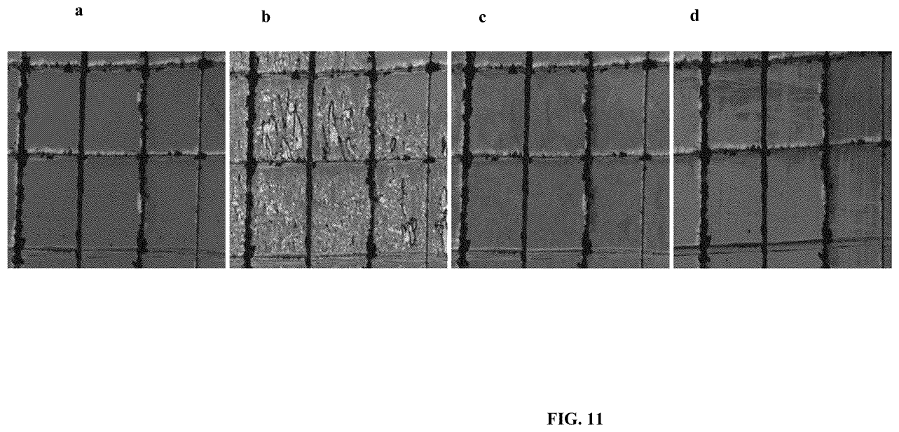

FIG. 11 shows differential interference contrast images of a cross-hatched, 180° tape pull adhesion test performed on a n≈1.11 film for the film before the test (image a), the film after the test (image b) showing adhesive residue left behind by the tape, the appearance of the film after dissolving away the adhesive residue in solvent (image c), and scratches and removal of the film after rubbing with a cotton-tipped swab (image d). The images in FIG. 11 show a series of differential interference contrast microscopy images taken at different points during a cross-hatch tape-pull adhesion test. Following the 180° tape-pull, adhesive residue from the tape remains on the surface, indicating stronger adhesion between the nanoporous film and substrate than between the tape adhesive and its backing. Similar results were obtained with 3M 600 packing tape and 3M 105 tape. Rinsing the sample in acetone and isopropanol removes the adhesive residue and restores the original appearance of the nanoporous film with no delamination. Despite its strong adhesion to the substrate, the abrasion resistance of this film is poor. Image a shows that the film is easily scratched after rubbing with a cotton-tipped swab, and is totally removed after several passes. This film does, however, stand up well to the standard drag-and-drop procedure used to clean optical elements with a lens wipe and alcohol.

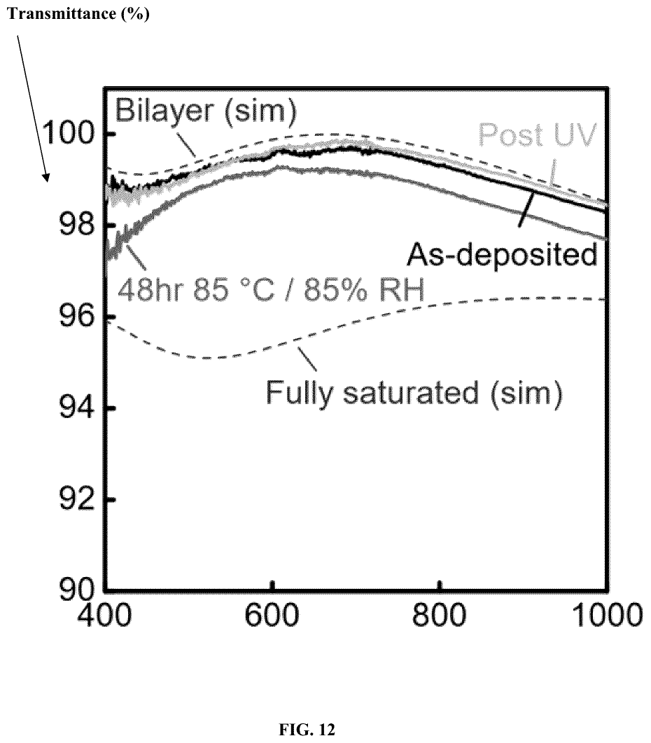

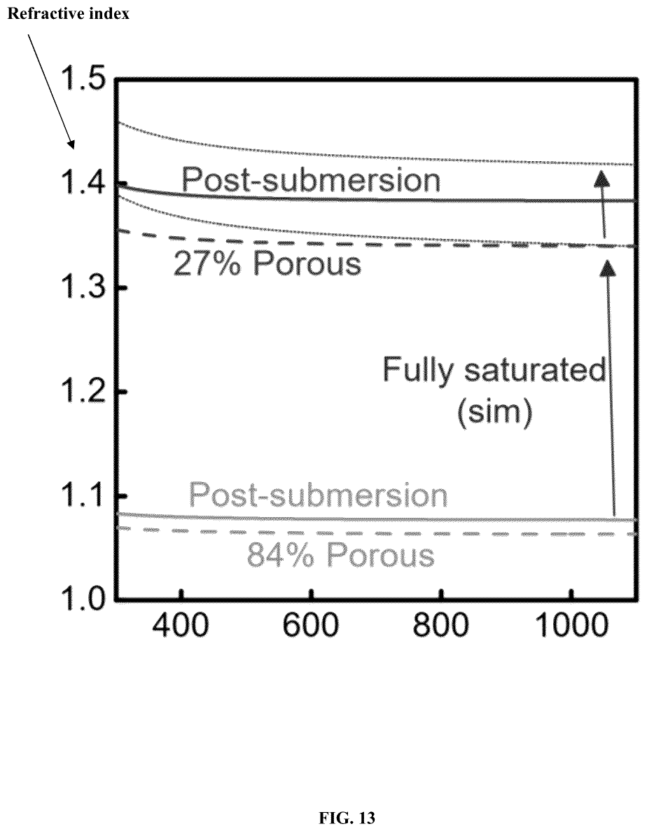

FIG. 12 shows normal incidence specular transmittance of a double-side AR coated fused silica wafer before and after UV and humidity environmental testing. Dashed red lines show the simulated transmission of the pristine coating and one that is fully saturated with water. FIG. 13 shows refractive index dispersion of nanoporous films before and after submerging the films in deionized water for 48 hrs (equivalent to roughly 7 suns). Whereas UV exposure has no effect on the transmittance, the hot and humid environment of the damp heat chamber (85° C., 85% relative humidity) causes to a slight decrease in transmittance. The simulated spectra depicted by the dashed lines result from a Bruggeman effective medium model where the void fraction in SiO₂ corresponds to air for the pristine case or water for the fully saturated case. Fully saturating the bilayer coating with water is predicted to increase the refractive index of its bottom (top) layer from n_{eff}=1.11 (n_{eff}=1.31) to n=1.37 (n_{eff}=1.41). The much larger decrease in transmission for the fully saturated model compared with the experimental data indicates relatively low water uptake by the coating.

FIG. 12 plots the normal incidence transmittance of a double-side AR coated fused silica wafer after 48 hrs of damp heat testing and (separately) accelerated UV exposure. The UV illumination is provided by a Xe arc lamp that delivers an intensity of ˜20 mWcm−² in the 200-400 nm wavelength range. FIG. 13 explores the refractive index change of two single layer films immersed in deionized water for 48 hrs. Modeling the refractive index increase of the n_{eff}=1.08 (n_{eff}=1.35) film suggests that water fills ˜5% (˜30%) of its porous volume. These results align well with the changes inferred for the bilayer AR coating in FIG. 12. In all cases, rinsing the samples in isopropanol or drying them at 200° C. on a hot plate restores their original refractive index/transmittance values.

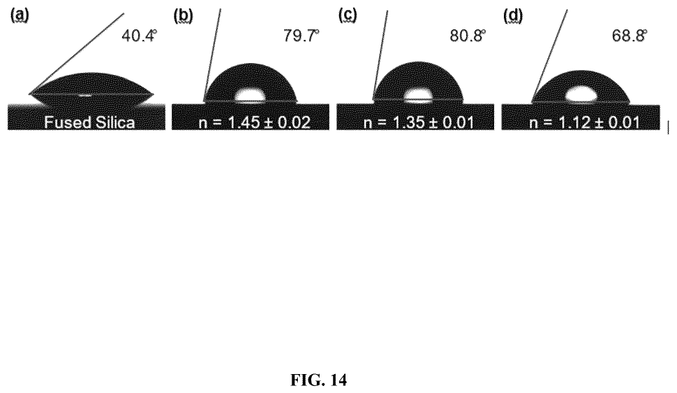

The nanoscale roughness of these films likely contributes to their moisture uptake resistance. FIG. 14 compares the water contact angle measured by with a calibrated goniometer (Rame-hart model 260) of bare fused silica to nanoporous films ranging from n=1.45 to n=1.12. All nanoporous films are found to have a higher contact angle and thus are more hydrophobic than neat fused silica.

### Impact of AR Coating Performance on Photovoltaic Energy Yield

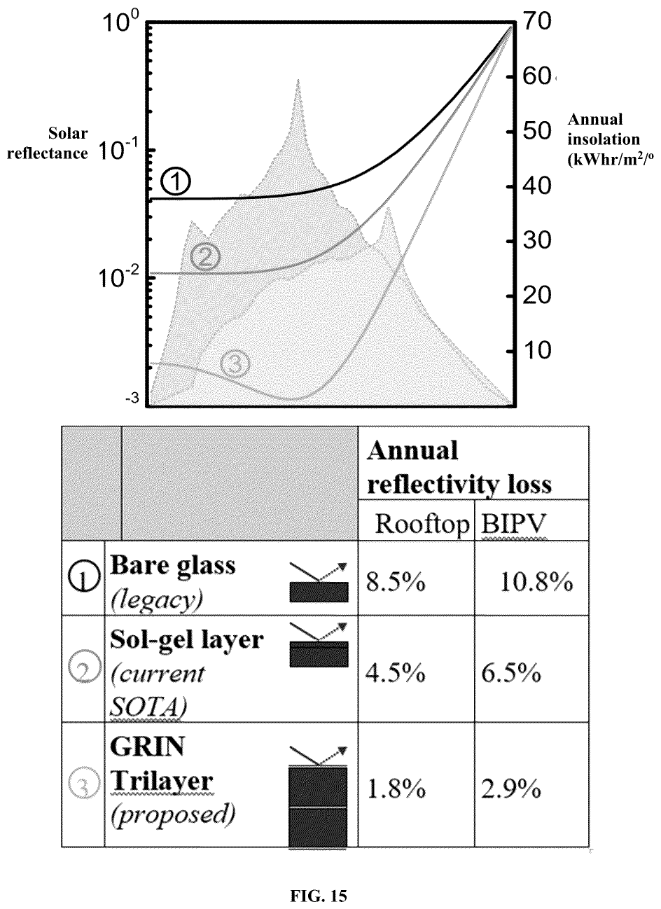

FIG. 15 shows solar spectrum-averaged (400-1100 nm) reflectivity as a function of incidence angle for bare glass (1), the single layer sol-gel nanoporous silica AR coating currently in use (2), and a trilayer coating following the results of this work (3). The table lists the annual reflected energy loss in each case based on the angular insolation distribution shown in the top plot for a typical rooftop (20° tilt, southfacing) and BIPV (90° tilt, southeast-facing) installation in Phoenix, AZ. The insolation distributions are calculated from the National Renewable Energy Laboratory solar position algorithm and typical meteorological year (TMY) hourly direct and diffuse irradiance data from PVWatts.

Reflection loss at the air/cover glass interface represents an 8-12% loss in annual energy yield for photovoltaic (PV) panels with no AR coating depending on their installation location and orientation. As a result, many module manufacturers employ AR-coated cover glass, which often consists of a ˜120 nm-thick layer of nanoporous silica (n_{eff}˜1.25) applied via a sol-gel process. This roughly halves the annual reflectivity loss as shown in FIG. 15; however, the remaining 4-6% loss is still one of the largest module-related losses outside of the cell itself in state-of-the-art PV panels. This is especially true for growing bifacial and building-integrated photovoltaic (BIPV) applications, where a larger fraction of the insolation is incident at wide angle where Fresnel reflectance is highest (FIG. 15).

Advancing beyond the current sol-gel single layer to a multilayer AR coating via the sputtering process described in this work could substantially reduce the remaining reflection loss as shown in FIG. 15. There, a 400 nm-thick step-graded trilayer coating (n=1.43, 1.27, and 1.12) is predicted to cut the annual reflectivity loss of rooftop and BIPV modules to 1.8% and 2.9%, respectively.

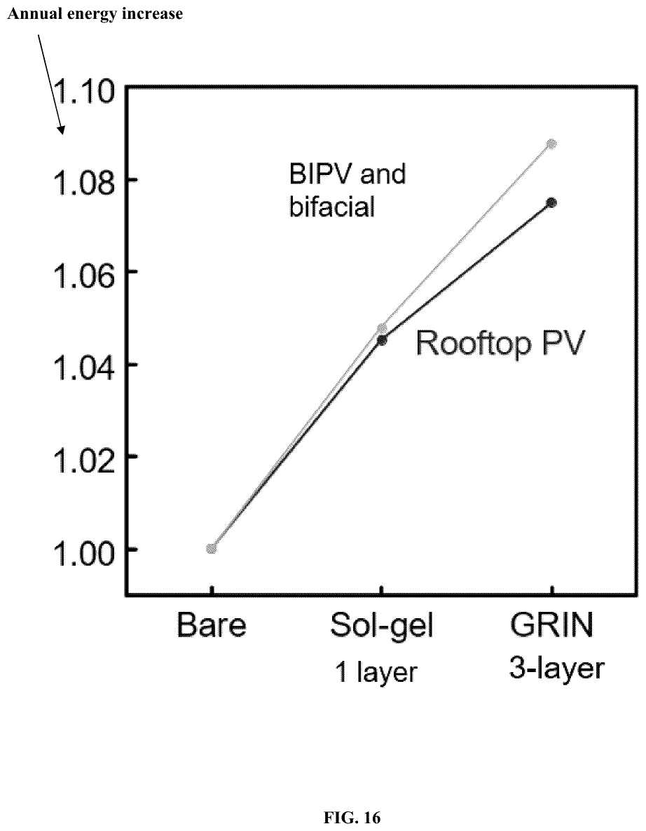

FIG. 16 shows fractional increase in annual energy yield calculated for a PV panel with a trilayer AR coating on its cover glass compared to one with bare cover glass or the current single layer sol-gel AR coating. The calculation is based on the angular insolation distribution for typical rooftop and BIPV installations shown in FIG. 15. The ˜4.5% improvement calculated for the single layer sol-gel coating relative to an uncoated panel is in good agreement with field testing, which lends credibility to the ˜7.5-9% boost predicted for the sputtered trilayer coating.

### REFERENCES

The entire contents of following references are incorporated herein by reference.
[1] Q. Chen, G. Hubbard, P. A. Shields, C. Liu, D. W. E. Allsopp, W. N. Wang, S. Abbott, Appl. Phys. Lett. 2009, 94, 263118.
[2] G. Tan, J.-H. Lee, Y.-H. Lan, M.-K. Wei, L.-H. Peng, I.-C. Cheng, S.-T. Wu, Optica 2017, 4, 678.
[3] H. Adachi, T. Hata, K. Wasa, in Handbook of Sputtering Technology (Second Edition), (Eds: K. Wasa, I. Kanno, H. Kotera), William Andrew, 2012, Ch. 5.
[4] J.-T. Chen, W.-C. Lai, C.-H. Chen, Y.-Y. Yang, J.-K. Sheu, L.-W. Lai, Opt. Express 2011, 19, 11873.
[5] CRC Handbook of Chemistry and Physics, (92nd Edition), Ed: W. M. Haynes, CRC Press, 2011.
[6] E. Centurioni, Appl. Opt. 2005, 44, 7532.
[7] B. Wang, C. J. Ruud, J. S. Price, H. Kim, N. C. Giebink, Nano Lett. 2019, 19, 787.
[8] X. Wang, H. Zhao, Y. Cao, Y. Su, H. Hui, J. Shen, J. Colloid Interface Sci. 2019, 555, 124.
[9] G. Prevo, E. Hon, O. D. Orlin, J. Mater. Chem. 2007, 17, 791.
[10] D. B. Mahadik, R. V. Lakshmi, H. C. Barshilia, Sol. Energy Mater. Sol. Cells 2015, 140 61.
[11] J.-Q. Xi, M. F. Schubert, J. K. Kim, E. F. Schubert, M. Chen, S.-Y. Lin, W. Liu, J. A. Smart, Nat. Photonics 2007, 1, 176.
[12] L. Ghazaryan, E.-B. Kley, A. Tünnermann, A. Szeghalmi, Nanotechnology 2016, 27, 255603.
[13] J. A. Dobrowolski, D. Poitras, P. Ma, H. Vakil, M. Acree, Appl. Opt. 2002, 41, 3075.
[14] M. Chen, H.-c. Chang, A. S. P. Chang, S.-Y. Lin, J.-Q. Xi, E. F. Schubert, Appl. Opt. 2007, 46, 6533.
[15] M. A. Azim, B. Gorr, H.-J. Christ, M. Heilmaier, U. Koch, M. Engelhard, Oxid. Met. 2017, 87, 89.
[16] M. Haldimann, A. Luible, M. Overend, Structural use of glass, International Association for Bridge and Structural Engineering, Zürich, Switzerland 2008.
[17] M. M. Braun, L. Pilon, Thin Solid Films 2006, 496, 505.
[18] P. Yeh, Optical Waves in Layered Media, John Wiley & Sons, Inc, Hoboken, NJ 2005.
[19] D. J. Wales, J. P. K. Doye, J. Phys. Chem. A 1997, 101, 5111.
[20] I. Reda, A. Andreas, Sol. Energy 2004, 76, 577.
[21] A. P. Dobos, PVWatts version 5 manual, National Renewable Energy Lab. (NREL), Golden, CO 2014.
[22] C. Schinke, M. R. Vogt, K. Bothe, in Photovoltaic Modeling Hand-book (Ed: M. F. Muller), WileyScrivener, Ltd, 2018, Ch. 3.
[23] C. Ballif, J. Dicker, D. Borchert, T. Hofmann, Sol. Energy Mater. Sol. Cells 2004, 82, 331
[24] A. Ganjoo, J. McCamy, A. Polcyn, Z. Ma, P. A. Medwick, in Springer Handbook of Glass (Eds: J. D., Musgraves, J. Hu, L. Calvez), Springer, 2019, Ch. 48.
[25] G. Bunea, G. Xavier, D. Rose, L. Nelson, J. Peurach, in Proceedings of the 25th European Photovoltaic Solar Energy Conference, Valencia, Spain 2010.

It should be understood that the disclosure of a range of values is a disclosure of every numerical value within that range, including the end points. It should also be appreciated that some components, features, and/or configurations may be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be apparent to those skilled in the art that numerous modifications and variations of the described examples and embodiments are possible considering the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof.

It should be understood that modifications to the embodiments disclosed herein can be made to meet a particular set of design criteria. Therefore, while certain exemplary embodiments of the composition and methods of using and making the same disclosed herein have been discussed and illustrated, it is to be distinctly understood that the invention is not limited thereto but may be otherwise variously embodied and practiced within the scope of the following claims.

What is claimed is:

1. A method of forming a nanoporous thin film, the method comprising:
co-sputtering SiO₂ and a sacrificial porogen to form a sacrificial porogen: SiO₂ composite film onto a substrate;
annealing the sacrificial porogen: SiO₂ composite film to form an annealed sacrificial porogen: SiO₂ composite film; and
dissolving at least a portion of the sacrificial porogen from the annealed sacrificial porogen: SiO₂ composite film.

2. The method of claim 1, wherein the substrate includes Si.

3. The method of claim 1, wherein the sacrificial porogen is ZnO or B₂O₃.

4. The method of claim 1, wherein co-sputtering involves magnetron sputtering.

5. The method of claim 4, wherein sputtering gas used in magnetron sputtering includes argon, xenon, oxygen, and/or nitrogen.

6. The method of claim 1, wherein annealing induces phase segregation of the sacrificial porogen: SiO₂ composite film.

7. The method of claim 6, wherein phase segregation yields nanoclusters of propogen embedded in a SiO₂ matrix.

8. The method of claim 1, wherein annealing involves rapid thermal annealing.

9. The method of claim 8, wherein rapid thermal annealing involves subjecting the sacrificial porogen: SiO₂ composite film to a temperature within a range from 750° C. and 850° C.

10. The method of claim 1, wherein annealing involves rapid thermal annealing the sacrificial porogen: SiO₂ composite fil within a N₂ environment.

11. The method of claim 1, wherein dissolving involves etching.

12. The method of claim 11, wherein etching involves immersing the annealed sacrificial porogen: SiO₂ composite film in an acid.

13. The method of claim 12, wherein the acid is HCl.

14. The method of claim 13, wherein the acid is 0.1M of HCl.

15. The method of claim 1, wherein dissolving is performed a room temperature.

16. The method of claim 1, wherein dissolving at least a portion of the sacrificial porogen from the annealed sacrificial porogen: SiO₂ composite film involves removing sacrificial porogen so that the content of the sacrificial porogen within the nanoporous thin film is within a range from 0% to 1%.

17. The method of claim 1, comprising tuning a refractive index of the nanoporous thin film by adjusting amount of sacrificial porogen used in the co-sputtering step.

18. The method of claim 1, comprising treating the nanoporous thin film to make it hydrophobic.

19. The method of claim 18, wherein treating the nanoporous thin film to make it hydrophobic involves fluorosilane treatment.

20. The method of claim 1, wherein the substrate is glass used for a lens, low-e glass, a display, or a cover glass on a solar panel.
